(19) United States
(12) Patent Application Publication
(10) Pub. No.: US 2008/0226835 A1
(43) Pub. Date: Sep. 18, 2008

(54) Production Method of Material Film and Production Apparatus of Material Film

(76) Inventors: Yasuhiko Kasama, Miyagi (JP); Kenji Omote, Miyagi (JP); Noboru Kudo, Miyagi (JP)

Correspondence Address: YOUNG & THOMPSON, 209 Madison Street, Suite 500, ALEXANDRIA, VA, 22314, US

(21) Appl. No.: 10/593,557

(22) PCT Filed: Mar. 18, 2005
(86) PCT No.: PCT/JP05/05016

§ 371 Date: Nov. 17, 2006

(30) Foreign Application Priority Data
Mar. 23, 2004 (JP) 2004-084003

(51) Int. Cl. C23C 14/48; C23C 14/14; C23C 14/12; C23C 16/44

(52) U.S. Cl. 427/525; 427/523; 427/531; 118/723 R

(57) ABSTRACT

According to a containing-fullerene production method by the background art, containment target ions obtained by ionizing containment target atoms have been irradiated to empty fullerene within a vacuum vessel. This has resulted in a problem of a lower formation efficiency of containing-fullerene, in case of forming containing-fullerene which internally contains an atom larger than a six-membered ring of fullerene. It is thus devised to irradiate ions having larger diameters and masses to a fullerene film, simultaneously with irradiation of containment target ions thereto. Since ions having larger masses collide with fullerene molecules, the fullerene molecules are largely deformed and openings thereof are enlarged. Containment target ions are caused to enter cages of fullerene molecules, thereby increasing a probability of formation of containing-fullerene.

### TECHNICAL FIELD

The present invention relates to a production method and a production apparatus for irradiating plasma or vapor including implantation target atoms, implantation target molecules, or the like onto a material such as fullerene, carbon nanotube, or the like within a vacuum vessel, thereby producing containing-fullerene, hetero-fullerene, or containing-nanotube.

2. Background Art

Patent-Unrelated Reference 1: “Nature and Application of Fullerene Plasma”, Journal of Plasma/Nuclear Fusion Academic Society, Vol. 75, No. 8, pp. 927-933, 1999 August

Patent-related reference 1: Japanese Patent Application No. 2004-001362

Containing-fullerenes are materials which are made of spherical clusters of carbon molecules known as fullerenes and containment target atoms such as alkali metal contained therein, and which are expected to be applied to electronics, medical treatment, and the like. Known as a production method of containing-fullerene is a method (patent-unrelated reference 1) configured to shoot alkali metal vapor to a hot plate heated within a vacuum vessel to thereby generate plasma, and to inject fullerene vapor into the generated plasma flow, thereby depositing containing-fullerene on a deposition-assistance substrate arranged downstream of the plasma flow.

Shooting the alkali metal gas generated by a sublimation oven onto the heated hot plate, generates alkali metal plasma including alkali metal ions and electrons by contact ionization. The generated plasma is confined within the vacuum vessel by a uniform magnetic field formed by an electromagnetic coil arranged around a vacuum chamber, and is established into a plasma flow flowing in the magnetic field direction from the hot plate. Injected into the plasma flow is fullerene vapor comprising C₆₀ by a fullerene sublimation oven arranged in the course of the plasma flow, so that electrons constituting the plasma flow attach to C₆₀ having a larger electron affinity, thereby generating negative ions of C₆₀. As a result, the plasma flow is brought into alkali metal/fullerene plasma mixedly including therein positive ions of the alkali metal, negative ions of fullerene, and residual electrons, based on the following reactions in case of adoption of lithium as the alkali metal, for example:

Li→Li⁺+e⁻

C₆₀+e^{-→C}₆₀⁻

There is arranged a deposition-assistance substrate downstream of such a plasma flow and the deposition-assistance substrate is brought to have a positive bias voltage applied thereto, so that alkali metal ions having smaller masses are decelerated and fullerene ions having larger masses are accelerated to increase interaction between alkali metal ions and fullerene ions in a manner that alkali metal ions and fullerene ions collide with one another by an action of coulomb attractive forces therebetween, resulting in production of containing-fullerene.

(Fullerene-Plasma Reaction Scheme)

To cause an atom to be internally contained in a cage of a fullerene molecule, it is required to collide a containment target atom with fullerene by a relatively large energy. However, excessively higher collision energies between a containment target atom and a fullerene molecule lead to breakage of the fullerene molecule, whereas excessively lower collision energies rarely lead to containment. Thus, to improve a production efficiency of containing-fullerenes, it is insufficient to merely improve a collision probability, and it is further required to control a collision energy. Although it has been possible to control a collision probability by virtue of the conventional containing-fullerene production method based on the fullerene/plasma reaction scheme, it has been impossible to control a collision energy.

As such, the present inventors have devised: in a scheme where alkali metal plasma is irradiated to a deposition-assistance substrate and fullerene vapor is simultaneously shot toward the deposition-assistance substrate, or where alkali metal plasma is irradiated to a fullerene film previously deposited on a deposition-assistance substrates; to apply a negative bias voltage to the deposition-assistance substrate and control the bias voltage to thereby give acceleration energies to alkali metal ions, thereby implanting alkali metal ions into a fullerene film (ion implantation scheme). This allows collision energies between containment target atoms and fullerene to be controlled by the bias voltage applied to the deposition-assistance substrate. This technique has been filed as a patent application according to the patent-related reference 1. Nonetheless, this technique has not been yet laid open to public inspection as of the filing date of this patent application, and thus is not a known technique.

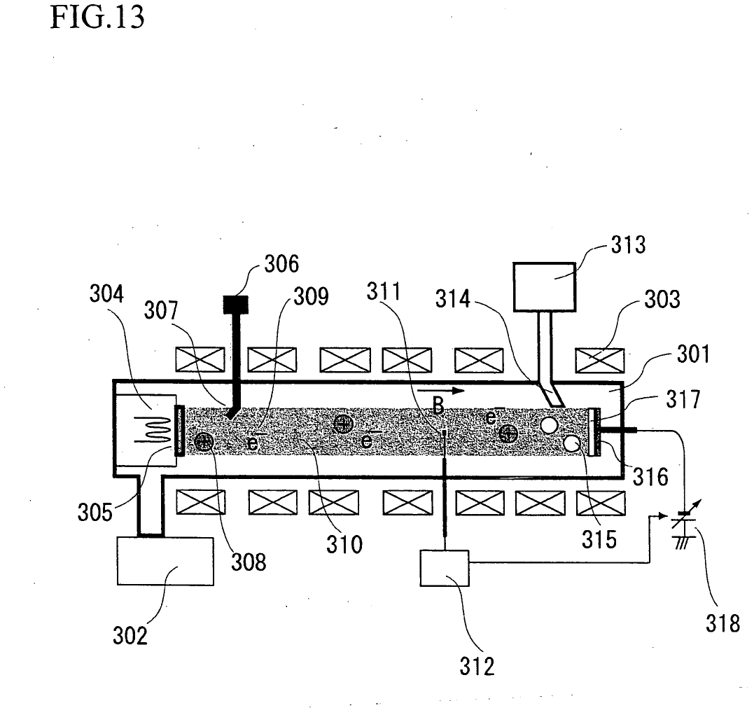

FIG. 13 is a cross-sectional view of a material film production apparatus according to the background art of the present invention. The production apparatus according to the background art is constituted of a vacuum vessel 301, an electromagnetic coil 303, means for generating plasma of alkali metal as a containment target atom, a deposition-assistance substrate 316, and a bias voltage control power supply 318. The vacuum vessel 301 is evacuated to a degree of vacuum of about 10⁻⁴ Pa by a vacuum pump 302. The alkali metal plasma generation means is constituted of a heating filament 304, a hot plate 305, an alkali metal sublimation oven 306, and an alkali metal gas introduction pipe 307. When the alkali metal vapor generated by the sublimation oven 306 is shot to the hot plate 305 from the alkali metal gas introduction pipe 307, alkali metal atoms are ionized on the high-temperature hot plate and thermoelectrons are simultaneously discharged from the hot plate, thereby generating plasma including alkali metal ions and electrons. The thus generated plasma is confined within a magnetic field direction within the vacuum vessel 301 along a uniform magnetic field formed by the electromagnetic coil 303, and established into a plasma flow 310 flowing from the hot plate 305 toward a deposition-assistance substrate 316.

Applied to the deposition-assistance substrate 316 is a negative bias voltage by the bias voltage control power supply 318. Alkali metal ions in the plasma are provided with acceleration energies by the bias voltage applied to the deposition-assistance substrate, and irradiated toward the deposition-assistance substrate. Simultaneously, fullerene is sublimated by a fullerene sublimation oven 313, and shot to the deposition-assistance substrate 316 from a fullerene gas introduction pipe 314. Alkali metal ions collide with fullerene molecules on the deposition-assistance substrate 316 or near the deposition-assistance substrate 316, thereby producing alkali-metal-containing fullerene.

### DISCLOSURE OF THE INVENTION

### Problem to be solved by the Invention

According to the production method of the background art, it is possible to precisely control a collision energy (acceleration energy) of the factors (collision probability and collision energy) which govern a production efficiency of containing-fullerene, by the bias voltage to be applied to the deposition-assistance substrate. In turn, control of collision probability has been conducted by controlling a density of alkali metal ions or a density of fullerene molecules, by temperature setting of each sublimation oven. Higher sublimation temperatures lead to larger sublimation amounts of alkali metal or fullerene to thereby increase ion densities or molecular densities thereof, thereby allowing an increased collision probability. However, since there is required a longer time up to obtainment of a stabilized temperature in case of the control based on sublimation temperature, and sublimation amounts depend on not only sublimation temperatures but also a residual amount of material filled in the applicable oven, an amount of material solidified on the introduction pipe and accumulated thereon, and the like, it has been difficult to precisely control sublimation amounts by controlling sublimation temperatures, respectively.

In turn, since there has been such a problem that a generation reaction of hydrogenated fullerene is promoted when a density of alkali metal ions is high as compared with a density of fullerene molecules such that a production efficiency of containing-fullerene is deteriorated, it has been required to precisely control an ion density so as to also restrict generation of hydrogenated fullerene.

Moreover, the conventional fullerene/plasma reaction scheme and the ion implantation scheme according to the background art have each been accompanied by such a problem that it is difficult to implant a relatively large containment target atom into fullerene.

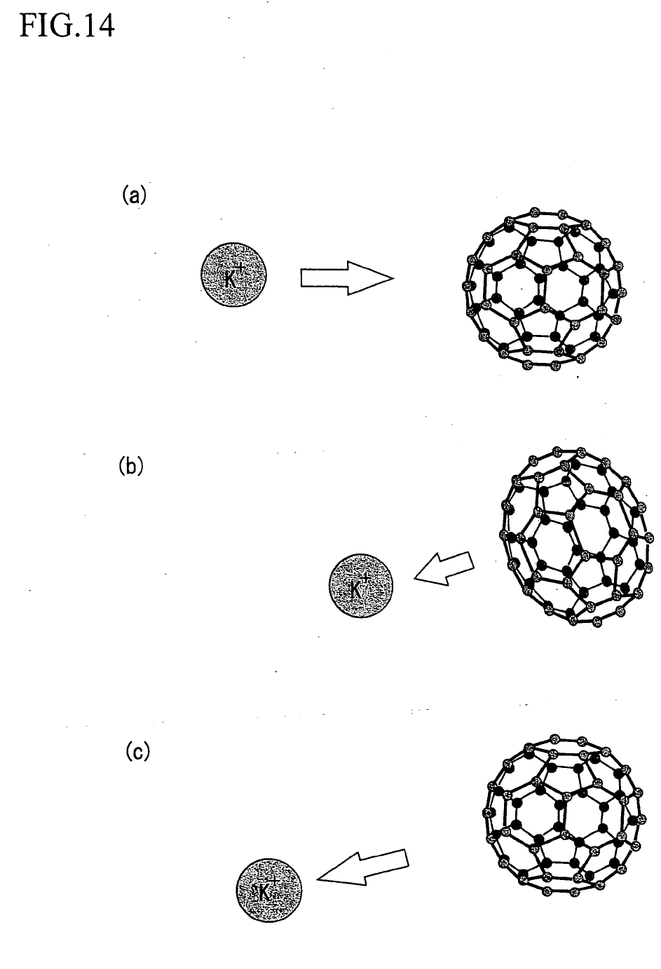

FIG. 14 is a view showing collision between particles in an attempt to form containing-fullerene by implanting a K ion as a containment target atom into an empty fullerene molecule comprising C₆₀ by the production apparatus according to the background art. The K ion is provided with an acceleration energy by the negative bias voltage applied to the deposition-assistance substrate, and is moved toward the fullerene molecule (FIG. 14(a)). Although the collision of the K ion with the fullerene molecule leads to deformation of a cage, the deformation is not so large because of a relatively small mass of the K ion. Additionally, since C₆₀ includes six-membered rings having an averaged diameter of 2.48□ whereas a K ion has a diameter of 2.76□ such that C₆₀ has openings each smaller than the K ion, the fullerene molecule is only slightly deformed in most cases even by collision of the K ion therewith (FIG. 14(b)) resulting in that the K ion is not internally contained in the fullerene molecule (FIG. 14(c)).

Sizes of containment target atom ions vary depending on kinds of containment target atom. In case of alkali metals, since Li, Na and the like each have a smaller ion diameter and provide higher containment probabilities even by the ion implantation scheme by the background art, it is possible to generate a relatively large amount of containing-fullerene. However, such a scheme has failed to obtain a sufficiently higher containment probability, even when attempting to internally contain larger ions such as K, Rb and the like.

Further, containing-fullerene is rarely formed in case of relatively large containment target atoms such as K, Rb, and the like, particularly in case of a lower acceleration energy for ion implantation. Contrary, in case of higher acceleration energies, for example, when a K ion is irradiated to a deposited fullerene film at an acceleration energy of 80 eV, the deposited fullerene film is problematically broken due to sputtering. Thus, there has been such a problem that an optimum condition for an acceleration energy for forming containing-fullerene is not obtained even by higher and lower energies.

### Means for solving the Problem

The present invention (1) resides in a material film production method, characterized in that the method comprises the steps of:

generating plasma including implantation target ions;

applying a control voltage to an electric potential body in contact with the plasma to thereby control a density of the implantation target ions;

irradiating the plasma toward a deposition-assistance substrate;

applying a bias voltage of a polarity opposite to that of the implantation target ions to the deposition-assistance substrate, to thereby provide the implantation target ions with acceleration energies, respectively; and

implanting the implantation target ions into a material film.

The present invention (2) resides in the material film production method of invention (1), characterized in that the method further comprises the step of:

measuring an electric current flowing between the deposition-assistance substrate and a bias power supply for applying the bias voltage thereto, to thereby measure the density of the implantation target ions.

The present invention (3) resides in a material film production method, characterized in that the method comprises the steps of:

generating plasma including containment target ions and collision ions having the same polarity as the containment target ions;

irradiating the plasma toward a deposition-assistance substrate;

applying a bias voltage of a polarity opposite to that of the containment target ions to the deposition-assistance substrate, to thereby provide the containment target ions and collision ions with acceleration energies, respectively; and

colliding the collision ions with material molecules constituting a material film, to thereby cause the material molecules to internally contain the containment target ions, respectively.

The present invention (4) resides in the material film production apparatus of any one of inventions 1 through 3, characterized in that the method further comprises the step of:

depositing the material film on the deposition-assistance substrate, simultaneously with the irradiation of the plasma toward the deposition-assistance substrate.

The present invention (5) resides in the material film production method of any one of inventions 1 through 3, characterized in that the method further comprises the step of:

irradiating the plasma onto the material film previously deposited on the deposition-assistance substrate.

The present invention (6) resides in a material film production method, characterized in that the method comprises the steps of:

generating plasma including collision ions;

irradiating the plasma toward a material film previously deposited on the deposition-assistance substrate;

simultaneously therewith, shooting vapor comprising containment target molecules toward the material film;

colliding the collision ions with material molecules constituting the material film; and

simultaneously therewith, causing the material molecules to internally contain the containment target molecules, respectively.

The present invention (7) resides in the material film production method of any one of inventions 1 through 6, characterized in that the method further comprises the step of:

transporting the generated plasma by a magnetic field to thereby irradiate the plasma toward the deposition-assistance substrate.

The present invention (8) resides in the material film production method of any one of inventions 1 through 7, characterized in that the material film is a film comprising fullerene or nanotube.

The present invention (9) resides in the material film production method of any one of inventions 1 through 5, 7, and 8, characterized in that the implantation target ions or the containment target ions are alkali metal ions, nitrogen ions, or halogen ions.

The present invention (10) resides in the material film production method of any one of inventions 6 through 8, characterized in that the containment target substance is TTF, TDAE, TMTSF, Pentacene, Tetracene, Anthracene, TCNQ, Alq₃, or F₄TCNQ.

The present invention (11) resides in the material film production method of any one of inventions 3 through 10, characterized in that the collision ions each have a diameter of 3.0□ or larger.

The present invention (12) resides in the material film production method of invention 11, characterized in that the collision ions are fullerene positive ions or fullerene negative ions, respectively.

The present invention (13) resides in a material film production apparatus comprising:

a vacuum vessel;

magnetic field generation means;

plasma generation means for generating plasma including implantation target ions;

an electric potential body configured to control a density of the implantation target ions by applying a control voltage to the electric potential body;

a deposition-assistance substrate for depositing a material film thereon; and

a bias power supply configured to apply a bias voltage to the deposition-assistance substrate.

The present invention (14) resides in the material film production apparatus of invention 13, characterized in that the electric potential body comprises electroconductive wires in a lattice pattern.

The present invention (15) resides in a material film production apparatus comprising:

a vacuum vessel;

magnetic field generation means;

plasma generation means for generating plasma including containment target ions;

collision ion generation means for generating collision ions;

a deposition-assistance substrate for depositing a material film thereon; and

a bias power supply-configured to apply a bias voltage to the deposition-assistance substrate.

The present invention (16) resides in a material film production apparatus comprising:

a vacuum vessel;

magnetic field generation means;

plasma generation means for generating plasma including collision ions;

a deposition-assistance substrate for depositing a material film thereon;

containment target molecule shooting means for shooting vapor including containment target molecules to the deposition-assistance substrate; and

a bias power supply configured to apply a bias voltage to the deposition-assistance substrate.

### EFFECT OF THE INVENTION

1. The electric potential body is arranged in the plasma to be irradiated to the material film, and the voltage to be applied to the electric potential body is controlled, thereby enabling a density of ions in the plasma to be controlled and controllability of the material film production process to be improved.

2. The electric potential body arranged in the plasma comprises electroconductive wires in the lattice pattern, thereby enabling a density of ions to be controlled to become uniform within a cross section of a plasma flow without disturbing the plasma flow by the electric potential body.

3. By measuring an electric current flowing between the deposition-assistance substrate and the bias power supply, it becomes possible to accurately measure a density of ions to be irradiated to the deposition-assistance substrate.

4. Since it is possible to produce fullerenes such as containing-fullerene, hetero-fullerene, and the like at a good efficiency, it becomes possible to attain mass-production of fullerenes for industrial utilization.

5. By simultaneously irradiating containment target ions and collision ions, or containment target molecules and collision ions toward material molecules constituting a material film, the material molecules are largely deformed to thereby increase a probability of containment of the containment target ions or containment target molecules into the material molecules, respectively.

6. Plasma is transported by utilizing the magnetic field, thereby enabling charged particles having a polarity opposite to that of implantation target ions, to be transported together with the implantation target ions. Thus, attractive forces act between the charged particles constituting the plasma in a manner to rarely diverge the plasma, thereby enabling achievement of a high density ion implantation even with a low energy.

7. By the method for simultaneously irradiating collision ions, it becomes possible to improve a production efficiency of fullerene internally containing an atom such as K, Rb, N, F, or the like which has been conventionally difficult in containment due to a larger ion diameter. For fullerenes which have been conventionally possible and each internally contain an atom such as Li, Na, or the like, it becomes possible to further improve a production efficiency thereof.

8. According to the method for simultaneously irradiating collision ions, it becomes possible to improve a production efficiency of containing-nanotubes internally containing molecules having larger diameters, respectively.

9. The simultaneous irradiation of collision ions enables containment target ions to be internally contained even at relatively lower acceleration energies, thereby making it unnecessary to conduct ion implantation at such higher acceleration energies which rather sputter a material film.

10. The collision ions are each made to have a diameter of 3.0□ or larger, thereby enabling a probability, that the collision ions are internally contained in fullerene, to be decreased.

11. Fullerene positive ions or fullerene negative ions are utilized as collision ions, so that containment target ions are internally contained in part of collision ions as well, thereby further improving a production efficiency of containing-fullerene.

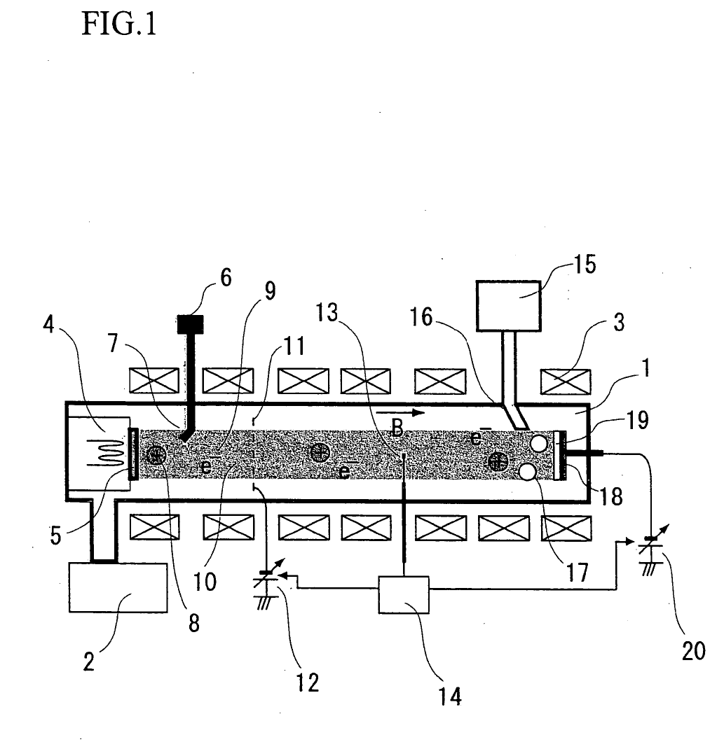

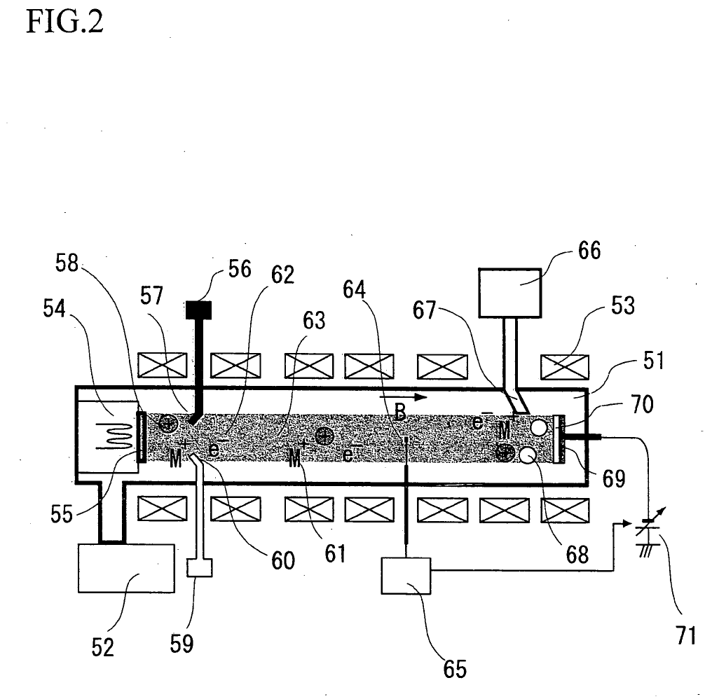

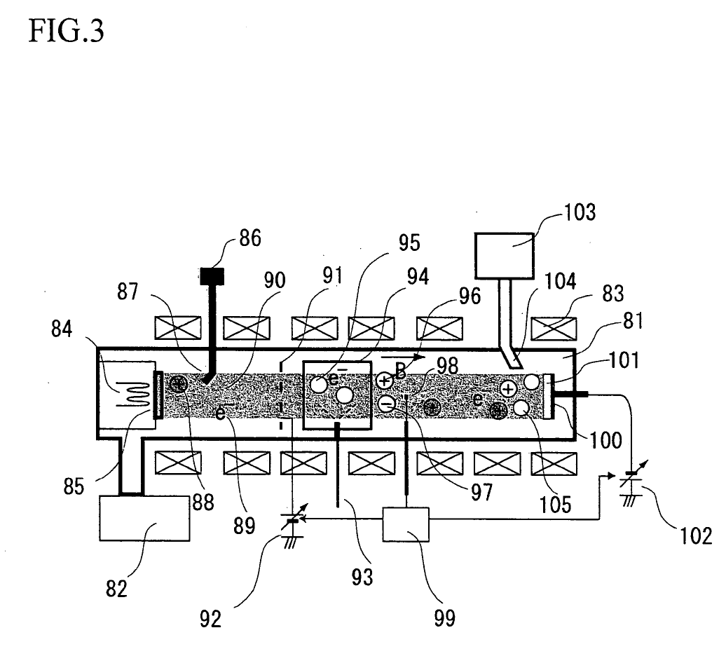

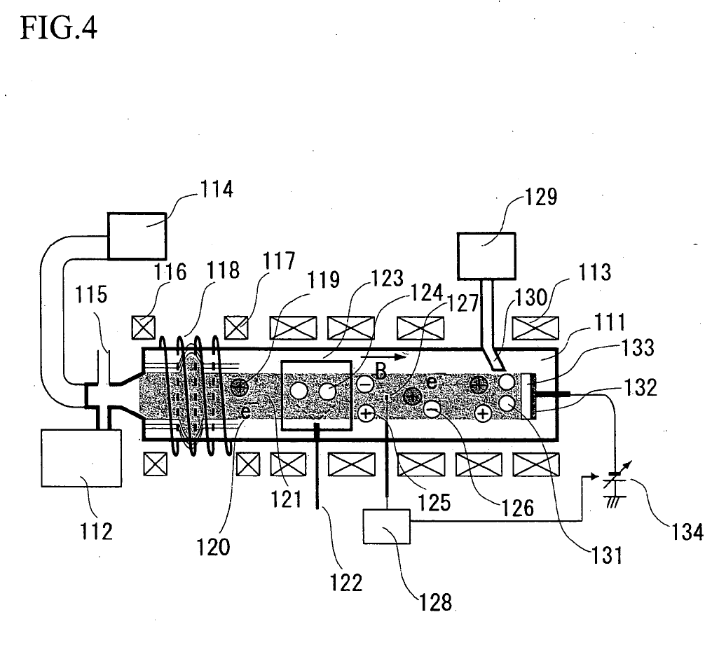

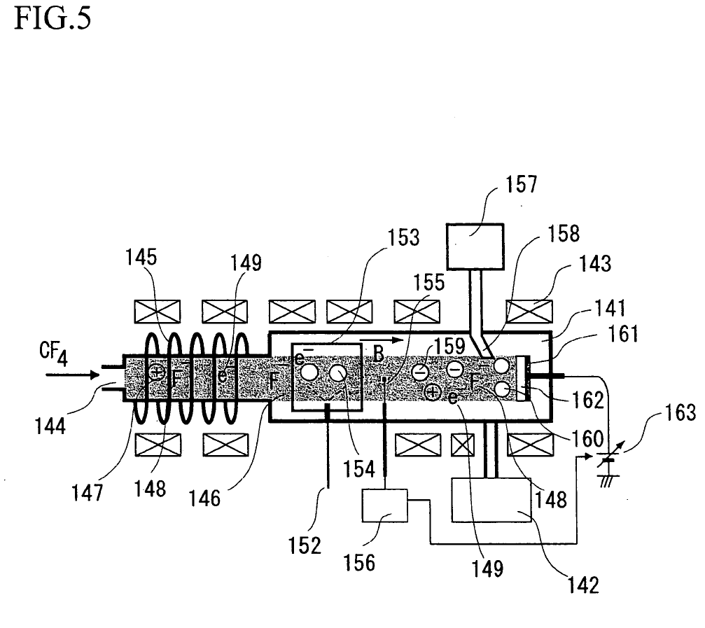

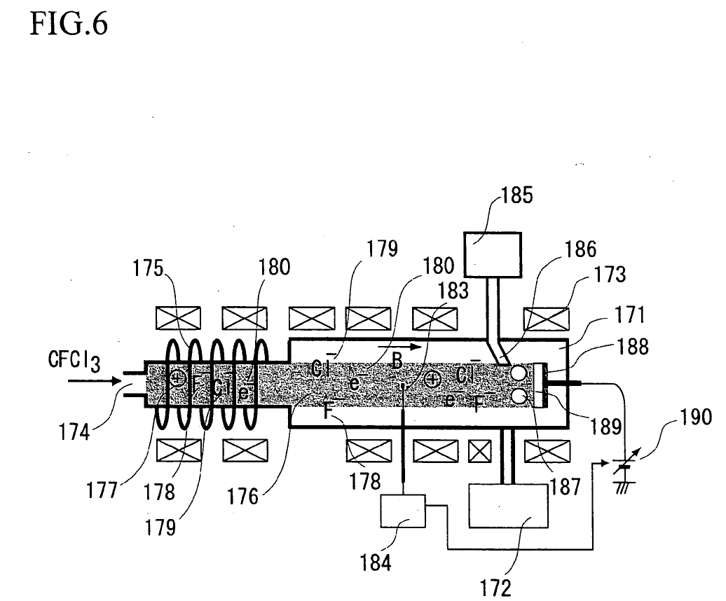

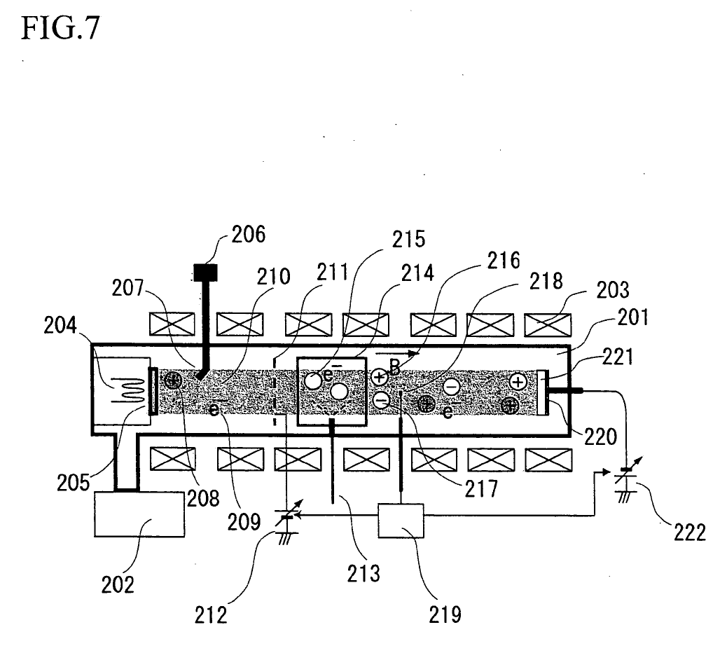

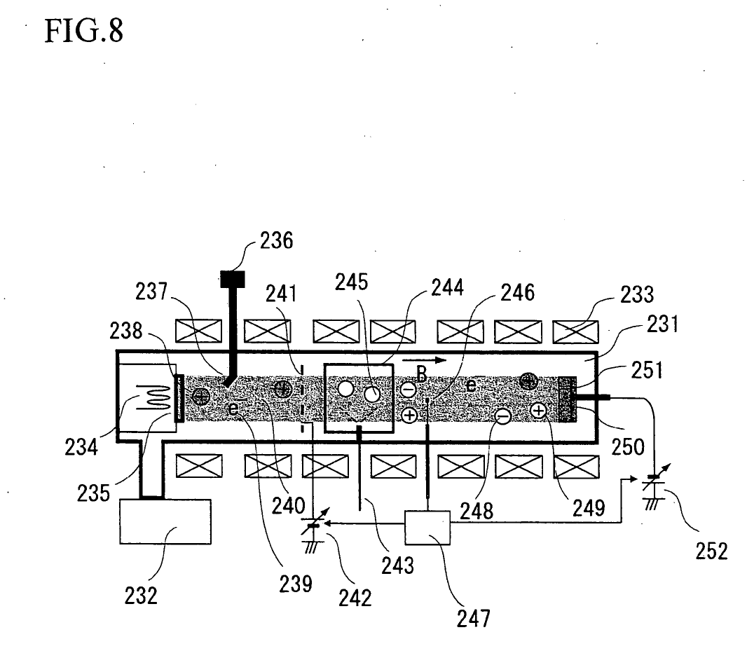

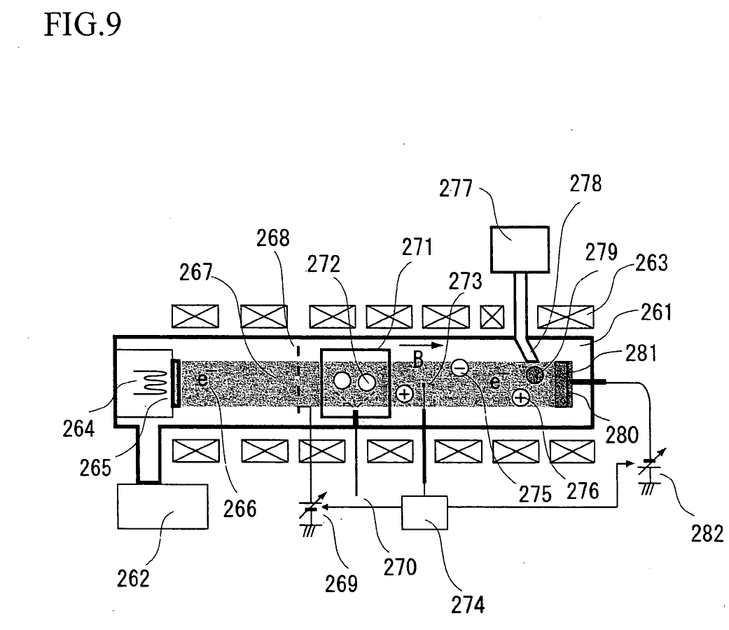

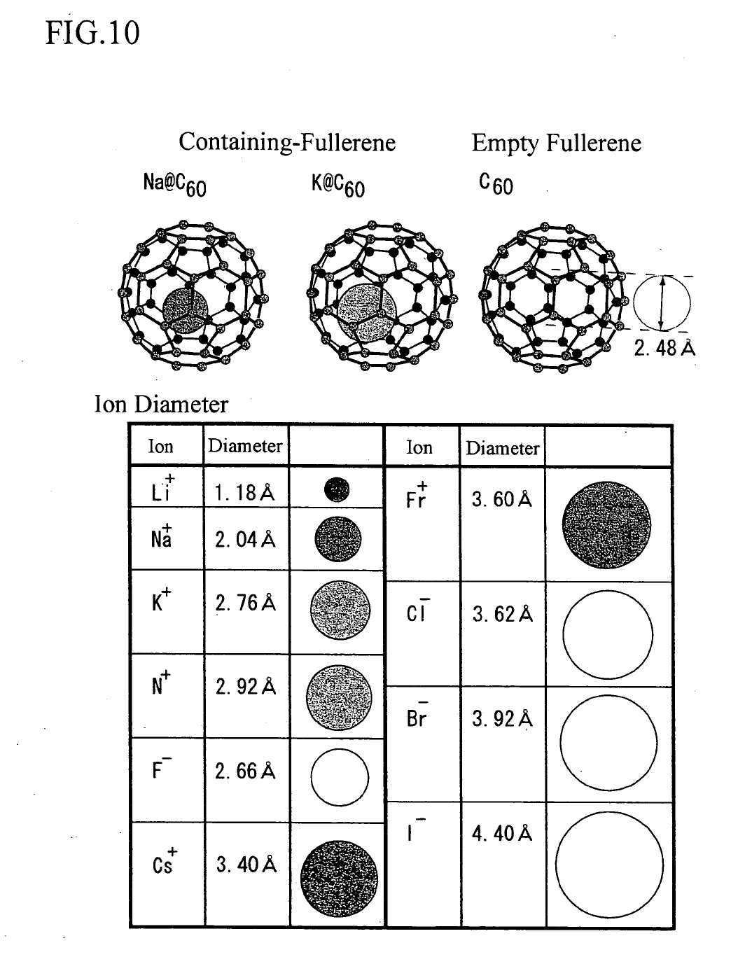

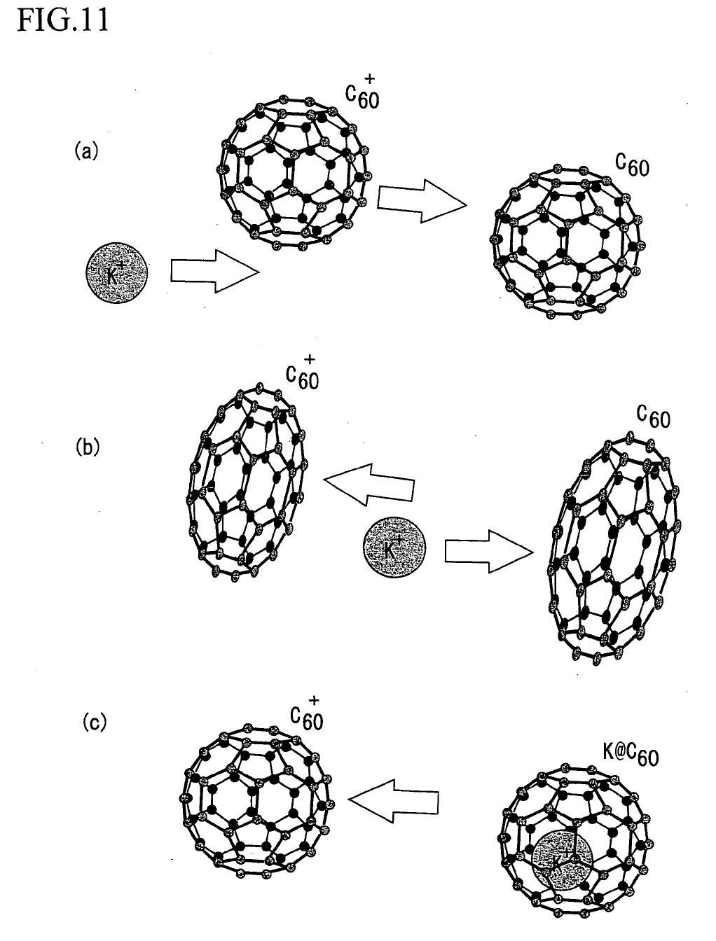

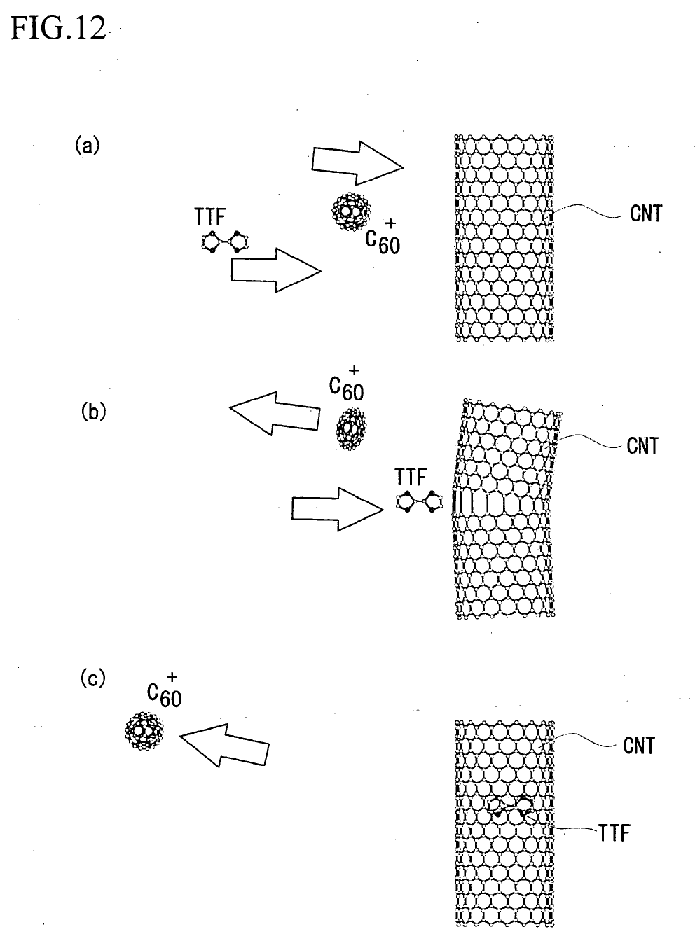

### BRIEF DESCRIPTION OF THE DRAWINGS

[FIG. 1] A cross-sectional view of a material film production apparatus according to a first concrete example of the present invention.

[FIG. 2] A cross-sectional view of a material film production apparatus according to a second concrete example of the present invention.

[FIG. 3] A cross-sectional view of a material film production apparatus according to a third concrete example of the present invention.

[FIG. 4] A cross-sectional view of a material film production apparatus according to a fourth concrete example of the present invention.

[FIG. 5] A cross-sectional view of a material film production apparatus according to a fifth concrete example of the present invention.

[FIG. 6] A cross-sectional view of a material film production apparatus according to a sixth concrete example of the present invention.

[FIG. 7] A cross-sectional view of a material film production apparatus according to a seventh concrete example of the present invention.

[FIG. 8] A cross-sectional view of a material film production apparatus according to an eighth concrete example of the present invention.

[FIG. 9] A cross-sectional view of a material film production apparatus according to a ninth concrete example of the present invention.

[FIG. 10] An explanatory view of sizes of containing-fullerene, empty fullerene, and ions.

[FIG. 11] An explanatory view of collision of containment target ion and collision ion with fullerene, according to the material film production method of the present invention.

[FIG. 12] An explanatory view of collision of containment target molecule and collision ion with carbon nanotube.

[FIG. 13] A cross-sectional view of a material film production apparatus according to the background art.

[FIG. 14] An explanatory view of collision of containment target ion with fullerene by virtue of the material film production method according to the background art.

### EXPLANATION OF REFERENCE NUMERALS

1, 51, 81, 111, 141, 171, 201, 231, vacuum vessel
261, 301
2, 52, 82, 112, 142, 172, 202, 232, vacuum pump
262, 302
3, 53, 83, 113, 116, 117, 143, 173, electromagnetic coil
203, 233,
263, 303
4, 54, 84, 204, 234, heating filament
264, 304
5, 55, 85, 205, 235, hot plate
265, 305
6, 56, 86, 206, 236, alkali metal sublimation oven
7, 57, 87, 207, 237, alkali metal gas introduction pipe
8, 58, 88, 208, 238, alkali metal ion
9, 62, 89, 120, 149, 180, 209, 239, electron
266, 309
10, 63, 90, 121, 146, 176, 210, 240, plasma flow
267, 310
11, 91, 211, 241, grid electrode
268
12, 92, 212, 242, grid voltage control power supply
269
13, 64, 98, 127, 155, 183, 218, 246, plasma prove
273, 311
14, 65, 99, 128, 156, 184, prove electric current
219, measurement device
247, 274, 312
15, 66, 93, 103, 122, 129, fullerene sublimation oven
152,
157, 185, 213, 270, 277,
313
16, 67, 104, 130, 158, 186, fullerene gas introduction
278, 314 pipe
17, 68, 95, 105, 124, 131, fullerene molecule
154,
160, 187, 215, 245, 272,
18, 69, 100, 132, 161, deposition-assistance substrate
188, 220,
250, 280, 316
19, 70, 101, 133, 162, 189, 221, 251, deposited film
281, 317
20, 71, 102, 134, 163, 190, bias voltage control power
222, supply
252, 282, 318
94, 123, 153, 214, re-sublimation cylinder
271
96, 125, 216, 249, fullerene positive ion
97, 126, 159, 217, 248, fullerene negative ion
275
59 collision atom sublimation oven
60 collision atom gas introduction pipe
61 collision ion
114 microwave transmitter
115 nitrogen gas introduction pipe
118 PMH antenna
119 nitrogen ion
144, 174 halogen gas introduction pipe
145, 175 high frequency induction coil
147, 177 positive ion
148, 178 fluorine ion
179 chlorine ion
279 containment target ion

### BEST MODE FOR CARRYING OUT THE INVENTION

(Control of Ion Density)

In order to precisely control a collision probability of an alkali metal ion with a fullerene molecule, it is devised to provide a grid electrode after a plasma generating portion and to apply a bias voltage to the grid electrode, thereby controlling a density of alkali metal ions to be irradiated to a deposition-assistance substrate. The bias voltage to be applied to the grid electrode allows control of an amount of alkali metal ions which pass through the grid electrode. By controlling the density of alkali metal ions to be irradiated to fullerene molecules to be shot out of a fullerene sublimation oven at a certain density, it becomes possible to precisely control a collision probability between alkali metal ions and fullerene molecules.

Note that, in the material film production method according to the present invention, there is utilized a uniform magnetic field generated by magnetic field generation means such as an electromagnetic coil, as a method for transporting: plasma generated by plasma generation means and including implantation target ions; from the plasma generation means, to a deposition-assistance substrate where implantation target ions are implanted into a material film. This enables transportation of charged particles of a polarity opposite to that of implantation target ions simultaneously with the implantation target ions, so that attractive forces act between the charged particles constituting the plasma, thereby rarely diverging the plasma. It is thus possible to achieve a high density ion implantation even with a low energy.

(Material Film Production Apparatus according to Control of Ion Density)

There will be explained a best mode of a production apparatus of the present invention configured to produce a material film such as containing-fullerene by controlling an ion density by a control voltage to be applied to a grid electrode, based on concrete examples.

### FIRST CONCRETE EXAMPLE

### Ion Implantation Scheme

FIG. 1 is a cross-sectional view of a material film production apparatus according to a first concrete example of the present invention. The first concrete example is a containing-fullerene production apparatus configured to implant alkali metal ions into fullerene to thereby produce alkali-metal-containing fullerene.

The production apparatus is constituted of a vacuum vessel 1, an electromagnetic coil 3, alkali metal plasma generation means, a grid electrode 11, a plasma prove 13, fullerene vapor deposition means, a deposition-assistance substrate 18, and a bias voltage control power supply 20.

The vacuum vessel 1 is evacuated to a degree of vacuum of about 10⁻⁴ Pa by a vacuum pump 2. The plasma generation means is constituted of a heating filament 4, a hot plate 5, an alkali metal sublimation oven 6, and an alkali metal gas introduction pipe 7. Alkali metal is heated by the sublimation oven 6, and the generated alkali metal gas is shot from the introduction pipe 7 onto the hot plate 5, so that alkali metal atoms are ionized on the high-temperature hot plate, thereby generating alkali metal ions. Simultaneously therewith, thermoelectrons are generated from the hot plate, thereby generating plasma including alkali metal ions 8 and electrons 9. The thus generated plasma is confined in a magnetic field direction within the vacuum vessel 1 along a uniform magnetic field formed by the electromagnetic coil 3, and is established into a plasma flow 10 flowing from the hot plate 5 toward the deposition-assistance substrate 18.

The plasma flow 10 generated by the plasma generation means firstly passes through the grid electrode 11. Applied to the grid electrode 11 is a control voltage by a grid voltage control power supply 12, thereby controlling a density of alkali metal ions and a temperature of electrons in the plasma. Particular limitations are not applied to as to which of positive voltage, earth voltage, and negative voltage the control voltage value is set at, and there is adopted an optimum condition taking account of a production efficiency of containing-fullerene, for example. It is also possible to make the control voltage variable and to control the voltage value based on values of an ion density, ion energy, and the like measured by the plasma prove 13, thereby optimizing a production efficiency of containing-fullerene.

Applied to the deposition-assistance substrate 18, to which the plasma flow 10 is irradiated, is a negative bias voltage by the bias voltage control power supply 20. Further, simultaneously with the plasma irradiation to the deposition-assistance substrate, fullerene vapor is shot to the deposition-assistance substrate 18 by the fullerene vapor deposition means. The fullerene vapor deposition means is constituted of a fullerene sublimation oven 15 and a fullerene gas introduction pipe 16. The fullerene sublimation oven 15 heats fullerene to thereby generate a fullerene gas, which is then shot to the deposition-assistance substrate 18 from the introduction pipe 16 having a tip end directed toward the deposition-assistance substrate 18. The alkali metal ions 8 within the plasma flow are provided with acceleration energies by the negative voltage applied to the deposition-assistance substrate 18. The alkali metal ions 8 collide with fullerene molecules 17 near the deposition-assistance substrate or on the deposition-assistance substrate, and are internally contained within the fullerene molecules 17, thereby depositing a film 19 including containing-fullerene on the deposition-assistance substrate 18. It is also possible that the bias voltage to be applied to the deposition-assistance substrate 18 is made variable, and the bias voltage value is controlled based on the values measured by the plasma prove 13, thereby optimizing a production efficiency of containing-fullerene.

It is also possible to measure an alkali metal ion density, an ion implantation amount, and the like, even by a method for arranging an ammeter between the bias voltage control power supply 20 and the deposition-assistance substrate 18, thereby measuring an electric current flowing through the deposition-assistance substrate. Further, it is possible to obtain a shooting velocity of fullerene vapor, by previously conducting vapor deposition of fullerene onto the deposition-assistance substrate so as to monitor a film thickness, and by measuring a timewise change of a thickness of a deposited film.

There can be controlled an alkali metal ion density within plasma by a voltage to be applied to the grid electrode to thereby precisely control densities of alkali metal ions and fullerene molecules, thereby allowing an improved production efficiency of containing-fullerene.

The above explained method for controlling an ion density by the grid electrode can be used not only in production of containing-fullerene where alkali metal acts as a containment target atom but also in production of containing-fullerene which internally contains another atom such as nitrogen, halogen, hydrogen, inert element, alkaline earth metal, or the like, in a manner to obtain the same effect as the production of alkali-metal-containing fullerene.

Note that, without limited to the production of containing-fullerene, it is also possible to optimize a production efficiency of a material film by arranging a grid electrode having a control voltage applied thereto after a plasma generating portion to thereby control an ion density within plasma, for: a containing-nanotube comprising a nanotube internally containing an atom or molecule; hetero-fullerene to be obtained by irradiating an ion(s) comprising a substitutional atom(s) toward fullerene so as to substitute carbon atoms constituting the fullerene by the substitutional atom(s); chemically modified fullerene to be obtained by irradiating ions of modification atoms or molecules, thereby adding a modifying group(s) to the fullerene; and the like.

(Irradiation of Collision Ion)

To improve a production efficiency of containing-fullerene internally containing a relatively large atom such as K, it is devised that, upon implantation of containment target atom ions (containment target ions) into fullerene, the fullerene is caused to be irradiated with ions (collision ions) of atoms (collision atoms) each having the same polarity as a containment target ion and each having a diameter and a mass larger than those of the containment target ion. Although the collision ions are each large in diameter and are thus internally contained in fullerene at an extremely low probability, the collision ions have larger masses and thus are capable of giving sufficiently large energies to fullerene upon collision therewith, thereby increasing deformation of the fullerene. This largely opens six-membered rings of the fullerene, so that the containment target ions, which have been irradiated simultaneously with the collision ions and which are smaller than the containment target ions, can be easily incorporated into the fullerene.

(Implantation Target Ion, Containment Target Ion, and Collision Ion)

There will be explained terms related to ions according to the material film production method of the present invention.

The term “implantation target ion” refers to an ion (charged particle) in a case that the ion is to be implanted into a material film or material molecule by an ion implantation scheme or plasma irradiation scheme. Examples of implantation target ions include atoms and molecules each having a positive electric charge or negative electric charge. As a result of conduction of ion implantation, there may be caused a physical or chemical change in a material film or material molecule, including situations where implantation target ions enter between molecules constituting a material film, as impurities, where implantation target ions bond to a material molecule to thereby cause chemical modification or heterogenization, and where there is caused such containment that implantation target ion(s) enter the interior of a cage-like or tubular material molecule.

Those implantation target ions, which are to be internally contained, are particularly called “containment target ions”, respectively. Those implantation target ions, which collide with a material molecule and which are not contained therein, are particularly called “collision ions”, respectively.

(Sizes of Fullerene and Ions)

The term “fullerene” used herein refers to a hollow carbon cluster substance represented by Cₙ (n=60, 70, 76, 78, 82, 84, . . . ), and examples thereof include C₆₀, C₇₀, and the like. Further, the term “fullerene” shall also be applied to those carbon cluster substances including: a repetitive bonded body (by ionic bond, covalent bond, or the like) of the same fullerene, such as a fullerene dimer; a mixture of a plurality of different fullerenes such as C₆₀ and C₇₀; and the like.

FIG. 10 is an explanatory view of sizes of containing-fullerene, empty fullerene, and containment target atom ions. Shown as fullerene is C₆₀ which is a representative carbon cluster molecule, and so are alkali metals, nitrogen, and halogens which are representative ones of containment target atoms. As shown in this figure, C₆₀ has six-membered rings having an averaged diameter of 2.48%.

Concerning combinations of containment target ions and collision ions, it is desirable to employ a positive ion such as that of Cs, Fr, or the like as a collision ion, in case that a containment target ion is a positive ion such as that of Li, Na, K, N, or the like. Further, it is desirable to employ a negative ion such as that of Cl, Br, I, or the like, in case that a containment target ion is a negative ion such as that of F. Equalizing an ion polarity of a containment target ion with that of a collision ion, enables simultaneous provision of acceleration energies to the containment target ion and collision ion by a bias voltage to be applied to a deposition-assistance substrate.

It is required for a collision ion to be in such a size which causes a sufficiently large deformation of a molecule constituting a material film, and which is scarcely contained in the molecule. It is desirable for a collision ion to have an ion diameter of 3.0□ or larger, since six-membered rings of C₆₀ have an averaged diameter of 2.48□.

Further, as a collision ion, it is possible to use not only an atomic ion to be provided by ionizing an applicable atom, but also a molecular ion to be provided by ionizing an applicable molecule such as a fullerene molecule. Fullerene molecules each have a larger electron affinity and a relatively small ionization energy. As such, it is possible to selectably ionize a fullerene molecule into a positive ion or negative ion, by controlling an energy of an electron upon colliding the electron with the fullerene molecule so as to ionize it. Concretely, it is possible to form a negative fullerene ion by collision of an electron having an energy less than 10 eV, and to form a positive fullerene ion by collision of an electron having an energy of 10 eV or higher.

As understood from the data of ion diameters, in case of those ions of Li, Na, and the like which are smaller than the averaged diameter of 2.48□ of six-membered rings of fullerene, it is possible to form containing-fullerene at a higher efficiency even without adopting collision ions. However, in case of relatively large ions such as those of K, N, F, and the like, it becomes possible to drastically improve a formation efficiency of containing-fullerene, only by irradiating collision ions to a fullerene film simultaneously with irradiation of containment target ions thereto. Further, even in case of relatively small ions such as those of Li, Na, or the like, it is rather possible to further improve a formation efficiency of containing-fullerene, by irradiating collision ions to a fullerene film simultaneously with irradiation of containment target ions thereto.

(Ion Implantation into Fullerene)

FIG. 11(a) through FIG. 11(c) are explanatory views of collision of a containment target ion and a collision ion with fullerene, according to the material film production method of the present invention. In FIG. 11(a), collided with a C₆₀ molecule formed on a deposition-assistance substrate, is a positive ion of C₆₀ acting as a collision ion. At a moment of collision, the C₆₀ molecule and the positive ion of C₆₀ are largely deformed. Further, a positive ion of K collides with the C₆₀ molecule (FIG. 11(b)). Since the C₆₀ molecule has been largely deformed, its openings have each been enlarged, so that the positive ion of K easily enters the cage of C₆₀ molecule, thereby forming K-containing C₆₀ (FIG. 11(c))

(Ion Implantation into Carbon Nanotube)

FIG. 12(a) through FIG. 12(c) are explanatory views of collision of a containment target molecule and a collision ion with a carbon nanotube, according to the material film production method of the present invention. In FIG. 12(a), collided with the carbon nanotube formed on a deposition-assistance substrate, is a positive ion of C₆₀ acting as a collision ion. At a moment of collision, the carbon nanotube and the positive ion of C₆₀ are largely deformed. Further, TTF as a containment target molecule collides with the carbon nanotube (FIG. 12(b)). Since the carbon nanotube has been largely deformed, its openings have each been enlarged, so that the TTF easily enters the cage of carbon nanotube, thereby forming TTF-containing carbon nanotube (FIG. 12(c)).

(Material Film Production Apparatus according to Irradiation of Collision Ions)

There will be explained a best mode of a production apparatus of the present invention configured to produce a material film such as containing-fullerene by simultaneously irradiating containment target ions and collision ions to a deposition-assistance substrate, based on concrete examples.

### SECOND CONCRETE EXAMPLE

FIG. 2 is a cross-sectional view of a material film production apparatus according to a second concrete example of the present invention. The second concrete example is a containing-fullerene production apparatus configured to irradiate alkali metal ions and collision ions to fullerene to thereby produce alkali-metal-containing fullerene. Usable as alkali metal is Li, Na, K, or the like. Usable as collision ion is that of Cs, Fr, or the like.

The production apparatus is constituted of a vacuum vessel 51, an electromagnetic coil 53, alkali metal plasma-generation means, a plasma prove 64, fullerene vapor deposition means, a deposition-assistance substrate 69, and a bias voltage control power supply 71.

The vacuum vessel 51 is evacuated to a degree of vacuum of about 10⁻⁴ Pa by a vacuum pump 52. The plasma generation means is constituted of a heating filament 54, a hot plate 55, an alkali metal sublimation oven 56, an alkali metal gas introduction pipe 57, a collision atom sublimation over 59, and a collision atom gas introduction pipe 60. Alkali metal is heated by the sublimation oven 56, and the generated alkali metal gas is shot from the introduction pipe 57 onto the hot plate 55. Simultaneously therewith, a collision atom gas generated by the sublimation oven 59 is shot from the introduction pipe 60 onto the hot plate 55, so that alkali metal atoms and collision atoms are ionized by contact ionization, thereby generating plasma including alkali metal ions, collision ions, and electrons. The thus generated plasma is confined in a magnetic field direction within the vacuum vessel 51 along a uniform magnetic field formed by the electromagnetic coil 53, and is established into a plasma flow 63 flowing from the hot plate 55 toward the deposition-assistance substrate 69.

Simultaneously with the plasma irradiation to the deposition-assistance substrate 69, the fullerene vapor deposition means shoots fullerene vapor toward the deposition-assistance substrate 69. The fullerene vapor deposition means is constituted of a fullerene sublimation oven 66 and a fullerene gas introduction pipe 67. Applied to the deposition-assistance substrate 69 is a negative bias voltage by the bias voltage control power supply 71. By virtue of the function of the bias voltage, alkali metal ions and collision ions acting as positive ions in plasma are provided with acceleration energies near the deposition-assistance substrate 69, and collide with fullerene molecules near the deposition-assistance substrate or on the deposition-assistance substrate. Since collision ions having larger masses collide with fullerene molecules, the fullerene molecules are largely deformed and six-membered rings of the fullerene molecules are largely opened. As such, alkali metal ions colliding with fullerene molecules easily enter cages of the fullerene molecules, thereby increasing a formation efficiency of containing-fullerene. After collision, collision ions having larger ion diameters are not internally contained in fullerene molecules, and exhausted by the vacuum pump 52.

The plasma prove 64 is arranged in the plasma flow 63, to measure ion densities, ion energies, and the like of plasma. It is also possible that the bias voltage to be applied to the deposition-assistance substrate 69 is made variable, and the bias voltage value is controlled based on the values measured by the plasma prove 64, thereby optimizing a production efficiency of containing-fullerene.

### THIRD CONCRETE EXAMPLE

FIG. 3 is a cross-sectional view of a material film production apparatus according to a third concrete example of the present invention. The third concrete example is a containing-fullerene production apparatus configured to irradiate collision ions including alkali metal ions and C₆₀⁺ to fullerene to thereby produce alkali-metal-containing fullerene. Usable as alkali metal ion is Li⁺, Na⁺, K⁺, or the like.

The production apparatus is constituted of a vacuum vessel 81, an electromagnetic coil 83, alkali metal plasma generation means, a grid electrode 91, fullerene ion generation means, a plasma prove 98, fullerene vapor deposition means, a deposition-assistance substrate 100, and a bias voltage control power supply 102.

The vacuum vessel 81 is evacuated to a degree of vacuum of about 10⁻⁴ Pa by a vacuum pump 82. The plasma generation means is constituted of a heating filament 84, a hot plate 85, an alkali metal sublimation oven 86, and an alkali metal gas introduction pipe 87. The sublimation oven 86 generates an alkali metal gas which is shot from the introduction pipe 87 onto the hot plate 85, so that alkali metal atoms are ionized on the high-temperature hot plate and established into plasma including alkali metal ions and electrons. The thus generated plasma is confined in a magnetic field direction within the vacuum vessel 81 along a uniform magnetic field formed by the electromagnetic coil 83, and is established into a plasma flow 90 flowing from the hot plate 85 toward the deposition-assistance substrate 100.

The plasma flow 90 generated by the plasma generation means firstly passes through the grid electrode 91. Applied to the grid electrode 91 is a control voltage by a grid voltage control power supply 92, thereby controlling a density of alkali metal ions and a temperature of electrons in the plasma. The control voltage is preferably a positive voltage. More preferably, the control voltage is 10V or higher. Setting the control voltage to be a positive voltage enables a temperature of electrons in plasma to be raised. It is also possible to make the control voltage variable and to control the value of voltage to be applied to the grid electrode 91 based on a value of electron temperature measured by the plasma prove 98, thereby optimizing a production efficiency of containing-fullerene.

The fullerene ion generation means for generating fullerene ions into plasma is arranged downstream of the grid electrode 91. The fullerene ion generation means is constituted of a fullerene sublimation oven 93 and a re-sublimation cylinder 94. Introduced from the fullerene sublimation oven 93 into plasma are fullerene molecules 95 which are then affected by electrons in the plasma and ionized by them, thereby generating fullerene positive ions 96 and fullerene negative ions 97. At this time, electrons in plasma have been raised in electron temperature by an action of the grid electrode 91, thereby increasing a generation probability of fullerene positive ions. Particularly, the generation probability of fullerene positive ions can be increased by causing a voltage of 10V or higher to be applied to the grid electrode 91. As a result, the plasma flow 90 is established into plasma including positive ions of alkali metal, fullerene-positive ions, fullerene negative ions, and electrons.

Simultaneously with plasma irradiation to the deposition-assistance substrate 100, the fullerene vapor deposition means shoots fullerene vapor to the deposition-assistance substrate 100. The fullerene vapor deposition means is constituted of a fullerene sublimation oven 103 and a fullerene gas introduction pipe 104. The bias voltage control power supply 102 applies a negative bias voltage to the deposition-assistance substrate 100. By virtue of the action of the bias voltage, alkali metal ions as positive ions in plasma and collision ions comprising fullerene positive ions are provided with acceleration energies near the deposition-assistance substrate 100, and collide with fullerene molecules near the deposition-assistance substrate or on the deposition-assistance substrate. Since collision ions having larger masses collide with fullerene molecules, the fullerene molecules are largely deformed and six-membered rings of the fullerene molecules are largely opened. As such, alkali metal ions colliding with fullerene molecules easily enter cages of the fullerene molecules, thereby increasing a formation efficiency of containing-fullerene.

It is possible to measure ion densities, ion energies, and the like of plasma by the plasma prove 97. It is also possible that the bias voltage to be applied to the deposition-assistance substrate 100 is made variable, and the bias voltage value is controlled based on the values measured by the plasma prove 97, thereby optimizing a production efficiency of containing-fullerene.

### FOURTH CONCRETE EXAMPLE

FIG. 4 is a cross-sectional view of a material film production apparatus according to a fourth concrete example of the present invention. The fourth concrete example of the present invention is a containing-fullerene production apparatus configured to irradiate collision ions comprising nitrogen ions and C₆₀⁺ to fullerene to thereby produce nitrogen-containing fullerene.

The production apparatus is constituted of a vacuum vessel 111, an electromagnetic coil 113, nitrogen plasma generation means, fullerene ion generation means, a plasma prove 127, fullerene vapor deposition means, a deposition-assistance substrate 132, and a bias voltage control power supply 134.

The vacuum vessel 111 is evacuated to a degree of vacuum of about 10⁻⁴ Pa by a vacuum pump 112. The nitrogen plasma generation means is constituted of a plasma generation chamber, a nitrogen gas introduction pipe 115, a microwave transmitter 114, electromagnetic coils 116, 117, and a PMH antenna 118. Nitrogen gas is introduced from the nitrogen gas introduction pipe 115 into the plasma generation chamber, and atoms, molecules, and the like constituting the nitrogen gas are excited by the microwave transmitter 114 to thereby generate nitrogen plasma. The electromagnetic coils 116, 117 exemplarily comprise ones in circular shape for surrounding the plasma generation chamber and arranged in a mutually separated state, and electric currents are caused to flow through the electromagnetic coils in the same direction. There are formed strong magnetic fields near the electromagnetic coils 116, 117, respectively, and there is formed a weak magnetic field in an area inbetween the electromagnetic coils 116, 117. Since rebound of ions, electrons, and the like is caused at the strong magnetic fields, there is formed plasma temporarily confined and having a higher energy.

The PMH antenna 118 is provided for supplying a high-frequency power (13.56 MHz, MAX 2 kW) by changing phases of multiple coil elements, thereby resultingly causing a larger electric field difference between the coil elements. This causes the plasma generated within the plasma generation chamber, to become highly dense over the entire region. By constituting the plasma generation means in the above manner, it becomes possible to effectively generate plasma including numerous N⁺ ions each comprising one nitrogen atom and particularly having a higher excitation energy.

The thus generated plasma is confined in a magnetic field direction in the vacuum vessel 111 along a uniform magnetic field (B=2 to 7 kG) formed by the electromagnetic coil 113, and is established into a plasma flow 121 flowing from the plasma generation chamber toward the deposition-assistance substrate 132.

The fullerene ion generation means for generating fullerene ions in plasma is arranged downstream of the plasma generation means. The fullerene ion generation means is constituted of a fullerene sublimation oven 122 and a re-sublimation cylinder 123. Introduced from the fullerene sublimation oven 122 into plasma are fullerene molecules 124 which are then affected by electrons in the plasma and ionized by them, thereby generating fullerene positive ions 125 and fullerene negative ions 126. Since the electron temperature in the plasma is high, the generation probability of fullerene positive ions 125 is large. The plasma flow is established into plasma including positive ions of nitrogen, fullerene positive ions, fullerene negative ions, and electrons.

Simultaneously with plasma irradiation to the deposition-assistance substrate 132, the fullerene vapor deposition means shoots fullerene vapor to the deposition-assistance substrate 132. The fullerene vapor deposition means is constituted of a fullerene sublimation oven 129 and a fullerene gas introduction pipe 130. The bias voltage control power supply 134 applies a negative bias voltage to the deposition-assistance substrate 132. By virtue of the action of the bias voltage, nitrogen ions as positive ions in plasma and collision ions comprising fullerene positive ions are provided with acceleration energies near the deposition-assistance substrate 132, and collide with fullerene molecules near the deposition-assistance substrate or on the deposition-assistance substrate. Since collision ions having larger masses collide with fullerene molecules, the fullerene molecules are largely deformed and six-membered rings of the fullerene molecules are largely opened. As such, nitrogen ions colliding with fullerene molecules easily enter cages of the fullerene molecules, thereby increasing a formation efficiency of containing-fullerene.

It is possible to measure ion densities, ion energies, and the like of plasma by the plasma prove 127. It is also possible that the bias voltage to be applied to the deposition-assistance substrate 132 is made variable, and the bias voltage value is controlled based on the values measured by the plasma prove 127, thereby optimizing a production efficiency of containing-fullerene.

### FIFTH CONCRETE EXAMPLE

FIG. 5 is a cross-sectional view of a material film production apparatus according to a sixth embodiment of the present invention. The sixth embodiment is a containing-fullerene production apparatus configured to implant fluorine ions and collision ions comprising C₆₀⁺ into fullerene to thereby produce fluorine-containing fullerene.

The production apparatus is constituted of a vacuum vessel 141, an electromagnetic coil 143, fluorine plasma generation means, fullerene ion generation means, a plasma prove 155, fullerene vapor deposition means, a deposition-assistance substrate 161, and a bias voltage control power supply 163.

The vacuum vessel 141 is evacuated to a degree of vacuum of about 10⁻⁴ Pa by a vacuum pump 112. The fluorine plasma generation means is constituted of a plasma generation chamber, a source gas introduction pipe 144, and a high frequency induction coil 145. Introduced from the source gas introduction pipe 144 into the plasma generation chamber is a source gas such as CF₄, and there is flowed an alternating current through the high frequency induction coil 145 arranged around the plasma generation means to thereby excite particles constituting the source gas, thereby generating plasma including ions such as CF₃⁺, F⁻, and electrons. Included in the plasma are ions 147 such as CF₃⁺, in addition to fluorine ions 148 required for production of containing-fullerene. The thus generated plasma is confined in a magnetic field direction in the vacuum vessel 141 along a uniform magnetic field (B=2 to 7 kG) formed by the electromagnetic coil 143, and is established into a plasma flow flowing from the plasma generation portion toward the deposition-assistance substrate 162.

The fullerene ion generation means for generating fullerene ions in plasma is arranged downstream of the plasma generation means. The fullerene ion generation means is constituted of a fullerene sublimation oven 152 and a re-sublimation cylinder 153. Introduced from the fullerene sublimation oven 152 into plasma are fullerene molecules 154 which are then affected by electrons in the plasma and ionized by them, thereby generating fullerene positive ions and fullerene negative ions 159.

Simultaneously with plasma irradiation to the deposition-assistance substrate 161, the fullerene vapor deposition means shoots fullerene vapor to the deposition-assistance substrate 161. The fullerene vapor deposition means is constituted of a fullerene sublimation oven 157 and a fullerene gas introduction pipe 158. The bias voltage control power supply 163 applies a positive bias voltage to the deposition-assistance substrate 161. By virtue of the action of the bias voltage, fluorine ions as negative ions in plasma and collision ions comprising fullerene negative ions are provided with acceleration energies near the deposition-assistance substrate 161, and collide with fullerene molecules near the deposition-assistance substrate or on the deposition-assistance substrate. Meanwhile, positive ions such as CF₃⁺ unrequired for production of containing-fullerene are subjected to repulsive forces by the positive bias voltage, so that the positive ions are not irradiated to the deposition-assistance substrate. Since collision ions having larger masses collide with fullerene molecules, the fullerene molecules are largely deformed and six-membered rings of the fullerene molecules are largely opened. As such, fluorine ions colliding with fullerene molecules easily enter cages of the fullerene molecules, thereby increasing a formation efficiency of containing-fullerene.

It is possible to measure ion densities, ion energies, and the like of plasma by the plasma prove 155. It is also possible that the bias voltage to be applied to the deposition-assistance substrate 161 is made variable, and the bias voltage value is controlled based on the values measured by the plasma prove 155, thereby optimizing a production efficiency of containing-fullerene.

### SIXTH CONCRETE EXAMPLE

FIG. 6 is a cross-sectional view of a material film production apparatus according to a seventh embodiment of the present invention. The seventh embodiment is a containing-fullerene production apparatus configured to implant fluorine ions and collision ions comprising chlorine ions into fullerene to thereby produce fluorine-containing fullerene.

The production apparatus is constituted of a vacuum vessel 171, an electromagnetic coil 173, fluorine/chlorine plasma generation means, a plasma prove 183, fullerene vapor deposition means, a deposition-assistance substrate 188, and a bias voltage control power supply 190.

The vacuum vessel 171 is evacuated to a degree of vacuum of about 10⁻⁴ Pa by a vacuum pump 172. The fluorine/chlorine plasma generation means is constituted of a plasma generation chamber, a source gas introduction pipe 174, and a high frequency induction coil 175. Introduced from the source gas introduction pipe 174 into the plasma generation chamber is a source gas such as CFCl₃, and there is flowed an alternating current through the high frequency induction coil 175 arranged around the plasma generation means to thereby excite particles constituting the source gas, thereby generating plasma including ions such as CF₃⁺, Cl⁻, F⁻, and electrons. Included in the plasma are unnecessary ions 177 such as CF₃⁺, in addition to fluorine ions 178 and chlorine ions 179 acting as collision ions required for production of containing-fullerene. The thus generated plasma is confined in a magnetic field direction in the vacuum vessel 171 along a uniform magnetic field (B=2 to 7 kG) formed by the electromagnetic coil 173, and is established into a plasma flow flowing from the plasma generation portion toward the deposition-assistance substrate 188.

Simultaneously with plasma irradiation to the deposition-assistance substrate 188, the fullerene vapor deposition means shoots fullerene vapor to the deposition-assistance substrate 188. The fullerene vapor deposition means is constituted of a fullerene sublimation oven 185 and a fullerene gas introduction pipe 186. The bias voltage control power supply 190 applies a positive bias voltage to the deposition-assistance substrate 188. By virtue of the action of the bias voltage, fluorine ions as negative ions in plasma and collision ions comprising chlorine ions are provided with acceleration energies near the deposition-assistance substrate 188, and collide with fullerene molecules near the deposition-assistance substrate or on the deposition-assistance substrate.

Meanwhile, positive ions such as CF₃⁺ unrequired for production of containing-fullerene are subjected to repulsive forces by the positive bias voltage, so that the positive ions are not irradiated to the deposition-assistance substrate. Since collision ions having larger masses collide with fullerene molecules, the fullerene molecules are largely deformed and six-membered rings of the fullerene molecules are largely opened. As such, fluorine ions colliding with fullerene molecules easily enter cages of the fullerene molecules, thereby increasing a formation efficiency of containing-fullerene.

It is possible to measure ion densities, ion energies, and the like of plasma by the plasma prove 183. It is also possible that the bias voltage to be applied to the deposition-assistance substrate 188 is made variable, and the bias voltage value is controlled based on the values measured by the plasma prove 183, thereby optimizing a production efficiency of containing-fullerene.

### SEVENTH CONCRETE EXAMPLE

FIG. 7 is a cross-sectional view of a material film production apparatus according to a seventh concrete example of the present invention. The seventh concrete example is a containing-fullerene production apparatus configured to irradiate alkali metal ions and collision ions comprising C₆₀⁺ onto a fullerene film on a deposition-assistance substrate to thereby produce alkali-metal-containing fullerene. Usable as alkali metal is Li, Na, K, or the like.

The production apparatus is constituted of a vacuum vessel 201, an electromagnetic coil 203, alkali metal plasma generation means, a grid electrode 211, fullerene ion generation means, a plasma prove 218, a deposition-assistance substrate 220, and a bias voltage control power supply 222.

The vacuum vessel 201 is evacuated to a degree of vacuum of about 10⁻⁴ Pa by a vacuum pump 202. The plasma generation means is constituted of a heating filament 204, a hot plate 205, an alkali metal sublimation oven 206, and an alkali metal gas introduction pipe 207. The sublimation oven 206 generates an alkali metal gas which is shot from the introduction pipe 207 onto the hot plate 205, so that alkali metal atoms are ionized on the high-temperature hot plate and established into plasma including alkali metal ions and electrons. The thus generated plasma is confined in a magnetic field direction within the vacuum vessel 201 along a uniform magnetic field formed by the electromagnetic coil 203, and is established into a plasma flow 210 flowing from the hot plate 205 toward the deposition-assistance substrate 220.

The plasma flow 210 generated by the plasma generation means firstly passes through the grid electrode 211. Applied to the grid electrode 211 is a control voltage by a grid voltage control power supply 212, thereby controlling a density of alkali metal ions and a temperature of electrons in the plasma. The control voltage is preferably a positive voltage. More preferably, the control voltage is 10V or higher. Setting the control voltage to be a positive voltage enables a temperature of electrons in plasma to be raised. It is also possible to make the control voltage variable and to control the value of voltage to be applied to the grid electrode 211 based on a value of electron temperature measured by the plasma prove 218, thereby optimizing a production efficiency of containing-fullerene.

The fullerene ion generation means for generating fullerene ions into plasma is arranged downstream of the grid electrode 211. The fullerene ion generation means is constituted of a fullerene sublimation oven 213 and a re-sublimation cylinder 214. Introduced from the fullerene sublimation oven 213 into plasma are fullerene molecules 215 which are then affected by electrons in the plasma and ionized by them, thereby generating fullerene positive ions 216 and fullerene negative ions 217. At this time, electrons in plasma have been raised in electron temperature by an action of the grid electrode 211, thereby increasing a generation probability of fullerene positive ions. Particularly, the generation probability of fullerene positive ions can be increased by causing a voltage of 10V or higher to be applied to the grid electrode 211. As a result, the plasma flow 210 is established into plasma including positive ions of alkali metal, fullerene positive ions, fullerene negative ions, and electrons.

Previously placed on the deposition-assistance substrate 220 is a deposited film 221 such as C₆₀, deposited by a vapor deposition method, for example. The bias voltage control power supply 222 applies a negative bias voltage to the deposition-assistance substrate 220. By virtue of the action of the bias voltage, alkali metal ions as positive ions in plasma and collision ions comprising fullerene positive ions are provided with acceleration energies near the deposition-assistance substrate 220, and collide with fullerene molecules constituting the deposited film on the deposition-assistance substrate. Since collision ions having larger masses collide with fullerene molecules, the fullerene molecules are largely deformed and six-membered rings of the fullerene molecules are largely opened. As such, alkali metal ions colliding with fullerene molecules easily enter cages of the fullerene molecules, thereby increasing a formation efficiency of containing-fullerene.

It is possible to measure ion densities, ion energies, and the like of plasma by the plasma prove 218. It is also possible that the bias voltage to be applied to the deposition-assistance substrate 220 is made variable, and the bias voltage value is controlled based on the values measured by the plasma prove 218, thereby optimizing a production efficiency of containing-fullerene.

Although the seventh concrete example has been described for a situation where positive ions acting as containment target atoms and collision ions comprising fullerene positive ions are simultaneously irradiated to the deposited film comprising fullerene on the deposition-assistance substrate, there can be obtained an effect of improving a production efficiency of containing-fullerene even in case of adopting positive ions such as those of Cs or Fr as collision ions instead of fullerene positive ions. Further, in case that containment target atoms to be irradiated to a deposited film are negative ions, there can be adopted negative collision ions to thereby obtain the same effect of improving a production efficiency of containing-fullerene as the case where containment target atoms comprises positive ions.

### EIGHTH CONCRETE EXAMPLE

FIG. 8 is a cross-sectional view of a material film production apparatus according to an eighth concrete example of the present invention. The eighth concrete example is a containing carbon nanotube production apparatus configured to irradiate alkali metal ions and collision ions comprising C₆₀⁺ to a carbon nanotube film on a deposition-assistance substrate to thereby produce an alkali metal-containing carbon nanotube. Usable as alkali metal is Li, Na, K, Cs, Fr, or the like.

The production apparatus is constituted of a vacuum vessel 231, an electromagnetic coil 233, alkali metal plasma generation means, a grid electrode 241, fullerene ion generation means, a plasma prove 246, a deposition-assistance substrate 250, and a bias voltage control power supply 252.

The vacuum vessel 231 is evacuated to a degree of vacuum of about 10⁻⁴ Pa by a vacuum pump 232. The plasma generation means is constituted of a heating filament 234, a hot plate 235, an alkali metal sublimation oven 236, and an alkali metal gas introduction pipe 237. The sublimation oven 236 generates an alkali metal gas which is shot from the introduction pipe 237 onto the hot plate 235, so that alkali metal atoms are ionized on the high-temperature hot plate and established into plasma including alkali metal ions and electrons. The thus generated plasma is confined in a magnetic field direction within the vacuum vessel 231 along a uniform magnetic field formed by the electromagnetic coil 233, and is established into a plasma flow 240 flowing from the hot plate 235 toward the deposition-assistance substrate 250.

The plasma flow 240 generated by the plasma generation means firstly passes through the grid electrode 241. Applied to the grid electrode 241 is a control voltage by a grid voltage control power supply 242, thereby controlling a density of alkali metal ions and a temperature of electrons in the plasma. The control voltage is preferably a positive voltage. More preferably, the control voltage is 10V or higher. Setting the control voltage to be a positive voltage enables a temperature of electrons in plasma to be raised. It is also possible to make the control voltage variable and to control the value of voltage to be applied to the grid electrode 241 based on a value of electron temperature measured by the plasma prove 246, thereby optimizing a production efficiency of containing carbon nanotube.

The fullerene ion generation means for generating fullerene ions into plasma is arranged downstream of the grid electrode 241. The fullerene ion generation means is constituted of a fullerene sublimation oven 243 and a re-sublimation cylinder 244. Introduced from the fullerene sublimation oven 243 into plasma are fullerene molecules 245 which are then affected by electrons in the plasma and ionized by them, thereby generating fullerene positive ions 249 and fullerene negative ions 248. At this time, electrons in plasma have been raised in electron temperature by an action of the grid electrode 241, thereby increasing a generation probability of fullerene positive ions. Particularly, the generation probability of fullerene positive ions can be increased by causing a voltage of 10V or higher to be applied to the grid electrode 241. As a result, the plasma flow 240 is established into plasma including positive ions of alkali metal, fullerene positive ions, fullerene negative ions, and electrons.

Previously placed on the deposition-assistance substrate 250 is a carbon nanotube film 251 deposited by a method such as vapor deposition method, laser vaporization method, arc discharge method, or the like. The bias voltage control power supply 252 applies a negative bias voltage to the deposition-assistance substrate 250. By virtue of the action of the bias voltage, alkali metal ions as positive ions in plasma and collision ions comprising fullerene positive ions are provided with acceleration energies near the deposition-assistance substrate 250, and collide with carbon nanotubes on the deposition-assistance substrate. Since collision ions having larger masses collide with carbon nanotubes, the carbon nanotubes are largely deformed and six-membered rings constituting the carbon nanotubes are largely opened. As such, alkali metal ions colliding with carbon nanotubes easily enter tubular bodies of the carbon nanotubes, thereby increasing a formation efficiency of containing carbon nanotubes.

It is possible to measure ion densities, ion energies, and the like of plasma by the plasma prove 246. It is also possible that the bias voltage to be applied to the deposition-assistance substrate 250 is made variable, and the bias voltage value is controlled based on the values measured by the plasma prove 246, thereby optimizing a production efficiency of containing carbon nanotubes.

The material film production method of the present invention is not limited to carbon nanotube, and can be applied to situations where a containment target substance is to be internally contained in another nanotube such as BN nanotube, and where atom(s), molecule(s), or the like as a containment target substance(s) other than alkali metals is/are to be internally contained in nanotubes. As collision ions, it is possible to adopt: positive ions such as those of Cs, Fr, or the like without limited to fullerene positive ions when containment target ions are positive ones; and negative ions such as fullerene negative ions, those of Cl, Br, I, or the like when containment target ions are negative ones.

### NINTH CONCRETE EXAMPLE

The present invention is applicable not only to a material film production method where ionizable atom(s), molecule(s), or the like is/are to be internally contained in a material film, but also to a molecule-containing material production method configured to internally contain molecule(s), which are hardly ionized, into a material film. FIG. 9 is a cross-sectional view of a material film production apparatus according to a ninth concrete example of the present invention. The ninth concrete example is a containing carbon nanotube production apparatus configured to irradiate collision ions comprising C₆₀⁺ to a carbon nanotube film on a deposition-assistance substrate and to simultaneously irradiate vapor comprising TTF molecules to the carbon nanotube film, thereby producing TTF-containing carbon nanotubes.

The production apparatus is constituted of a vacuum vessel 261, an electromagnetic coil 263, electron plasma generation means, a grid electrode 268, fullerene ion generation means, a plasma prove 273, TTF vapor deposition means, a deposition-assistance substrate 280, and a bias voltage control power supply 282.

The vacuum vessel 261 is evacuated to a degree of vacuum of about 10⁻⁴ Pa by a vacuum pump 262. The electron plasma generation means is constituted of a heating filament 264 and a hot plate 265. The hot plate 265 is heated by the heating filament 264 within the vacuum vessel to generate plasma comprising thermoelectrons, such that the thus generated plasma is confined in a magnetic field direction within the vacuum vessel 261 along a uniform magnetic field formed by the electromagnetic coil 263, and is established into a plasma flow 267 flowing from the hot plate 265 toward the deposition-assistance substrate 280.

The plasma flow 267 generated by the electron plasma generation means firstly passes through the grid electrode 268. Applied to the grid electrode 268 is a control voltage by a grid voltage control power supply 269, thereby controlling a temperature of electrons in the plasma. The control voltage is preferably a positive voltage. More preferably, the control voltage is 10V or higher. Setting the control voltage to be a positive voltage enables a temperature of electrons in plasma to be raised. It is also possible to make the control voltage variable and to control the value of voltage to be applied to the grid electrode 268 based on a value of electron temperature measured by the plasma prove 273.

The fullerene ion generation means for generating fullerene ions into plasma is arranged downstream of the grid electrode 268. The fullerene ion generation means is constituted of a fullerene sublimation oven 270 and a re-sublimation cylinder 271. Introduced from the fullerene sublimation oven 270 into plasma are fullerene molecules 272 which are then affected by electrons in the plasma and ionized by them, thereby generating fullerene positive ions 276 and fullerene negative ions 275. At this time, electrons in plasma have been raised in electron temperature by an action of the grid electrode 268, thereby increasing a generation probability of fullerene positive ions. Particularly, the generation probability of fullerene positive ions can be increased by causing a voltage of 10V or higher to be applied to the grid electrode 268. As a result, the plasma flow 267 is established into plasma including fullerene positive ions, fullerene negative ions, and electrons.

Previously placed on the deposition-assistance substrate 280 is a carbon nanotube film 281 deposited by a method such as vapor deposition method, laser vaporization method, arc discharge method, or the like. The bias voltage control power supply 282 applies a negative bias voltage to the deposition-assistance substrate 280. By virtue of the action of the bias voltage, collision ions comprising fullerene positive ions in plasma are provided with acceleration energies near the deposition-assistance substrate 280, and collide with carbon nanotubes on the deposition-assistance substrate. Since collision ions having larger masses collide with carbon nanotubes, the carbon nanotubes are largely deformed and six-membered rings constituting the carbon nanotubes are largely opened. Simultaneously with irradiation of collision ions to the deposited film 281, the TTF vapor deposition means shoots vapor comprising TTF molecules 279 to the deposited film 281. Although the TTF molecules 279 are not ionized, they are moved toward the deposited film 281 by virtue of the shooting action. As TTF molecules collide the deposited film 281, and the carbon nanotubes have been deformed and openings thereof have been enlarged, TTF molecules enter tubular bodies of the carbon nanotubes at a higher probability, thereby increasing a formation efficiency of containing carbon nanotubes.

It is possible to measure ion densities, ion energies, and the like of plasma by the plasma prove 273. It is also possible that the bias voltage to be applied to the deposition-assistance substrate 280 is made variable, and the bias voltage value is controlled based on the values measured by the plasma prove 273, thereby optimizing a production efficiency of containing carbon nanotubes.

It is further possible to apply a positive voltage to the deposition-assistance substrate 280 to thereby collide fullerene negative ions as collision ions with the deposited film 281, thereby improving a containment efficiency of containment target substances. In this case, it is unnecessary to generate fullerene positive ions and it is thus unnecessary to intentionally raise a temperature of electrons in plasma, thereby making it unnecessary to use the grid electrode 268 and grid voltage control power supply 269.

The material film production method of the present invention is not limited to carbon nanotube, and can be applied to situations where a containment target substance is to be internally contained in another nanotube such as BN nanotube, and where atom(s), molecule(s), or the like as a containment target substance(s) such as TDAE, TMTSF, Pentacene, Tetracene, Anthracene, TCNQ, Alq₃, F₄TCNQ other than TTF is/are to be internally contained in nanotubes. Collision ions are not limited to fullerene positive ions and fullerene negative ions, and it is also possible to use positive ions such as those of Cs, Fr, or the like, and negative ions such as those of Cl, Br, I, or the like by adopting collision ion generation means.

### EMBODIMENT

Although the present invention will be described hereinafter with reference to Examples, the present invention is not limited to such Examples.

### Production Example 1

### Production Example of Li-Containing Fullerene: Control of Ion Density

There was adopted the production apparatus shown in FIG. 1 comprising the cylindrical stainless vacuum vessel having the electromagnetic coil arranged therearound, to produce Li-containing fullerene. Used as L₁ and C₆₀ as applicable starting materials were Li manufactured by Aldrich and C₆₀ manufactured by Frontier Carbon Corporation, respectively.

The vacuum vessel 1 was evacuated to a degree of vacuum of 4.2×10⁻⁵ Pa, and the electromagnetic coil 3 was used to generate a magnetic field having a magnetic field strength of 0.2 T. The alkali metal sublimation oven 6 was filled with solid Li, and heated to a temperature of 480° C. to sublimate the Li, thereby generating an Li gas. The generated Li gas was introduced through the introduction pipe 7 heated to 500° C. and shot onto the hot plate 5 having a diameter of 6 cm and heated to 2,500° C. Li vapor was ionized on the surface of the hot plate 5, thereby generating a plasma flow comprising positive ions of Li and electrons. The grid electrode 11 was arranged in the course of the plasma flow, which was made of nonmagnetic stainless electroconductive wires having a lattice spacing of 1 mm, and the power supply 12 was caused to apply a control voltage to the grid electrode.

Further, shot into the generated plasma flow and toward the deposition-assistance substrate 18, was C₆₀ vapor which was obtained by heating fullerene to 610° C. to thereby sublimate it in the fullerene sublimation oven 15. Applied to the deposition-assistance substrate 18 in contact with the plasma flow was a bias voltage of −30V while applying the control voltage to the grid electrode 11 to thereby conduct deposition for about one hour, thereby depositing a thin-film including containing-fullerene on the surface of the deposition-assistance substrate 18.

The deposited film was collected and washed by pure water to remove Li and Li compound which were not internally contained, followed by elementary analysis to measure contents of Li and carbon to thereby obtain a content of containing-fullerene.

Elementary-Analysis Result:

| Control voltage | Content (relative value) of |
|---|---|
| of grid electrode | containing-fullerene |
| −10 V | 0.8 |
| 0 V | 0.9 |
| 10 V | 1.5 |
| 20 V | 1.2 |
| without voltage | 1 |
| application | |

From the content data of containing-fullerene, it has been shown that a production amount of containing-fullerene can be controlled by providing the grid electrode in the course of a plasma flow and by applying a control voltage to the grid electrode. Concerning the production conditions for the embodiment, it has been shown that the production efficiency of containing-fullerene is maximized when the grid control voltage is +10V.

### Production Example 2

### Production Example of K-Containing Fullerene: Irradiation of Collision Ion

There was adopted the production apparatus shown in FIG. 3 comprising the cylindrical stainless vacuum vessel having the electromagnetic coil arranged therearound, to produce K-containing fullerene. Used as K and C₆₀ as applicable starting materials were K manufactured by Aldrich and C₆₀ manufactured by Frontier Carbon Corporation, respectively.

The vacuum vessel 81 was evacuated to a degree of vacuum of 4.5×10⁻⁵ Pa, and the electromagnetic coil 83 was used to generate a magnetic field having a magnetic field strength of 0.3 T. The alkali metal sublimation oven 86 was filled with solid K, and heated to a temperature of 450° C. to sublimate the K, thereby generating a K gas. The generated K gas was introduced through the introduction pipe 87 heated to 480° C. and shot onto the hot plate 85 having a diameter of 6 cm and heated to 2,500° C. K vapor was ionized on the surface of the hot plate 85, thereby generating a plasma flow comprising positive ions of K and electrons. The grid electrode 91 was arranged in the course of the plasma flow, which was made of nonmagnetic stainless electroconductive wires having a lattice spacing of 1 mm, and the power supply 92 was caused to apply a control voltage of +15V to the grid electrode.

Further, introduced into the course of generated plasma was C₆₀ vapor obtained by heating fullerene to 630° C. to thereby sublimate it by the fullerene oven 93, thereby generating fullerene positive ions 96. Fullerene positive ions were generated so as to be used as collision ions, respectively. Further, shot toward the deposition-assistance substrate 100 was C₆₀ vapor obtained by heating fullerene to 600° C. to thereby sublimate it by the fullerene sublimation oven 103. Applied to the deposition-assistance substrate 100 in contact with the plasma flow was a bias voltage of −40V to thereby conduct deposition for about two hours, thereby depositing a thin-film including containing-fullerene on the surface of the deposition-assistance substrate 100.

The deposited film was collected and washed by pure water to remove K and K compound which were not internally contained, followed by elementary analysis to measure contents of K and carbon to thereby obtain a content of containing-fullerene.

Elementary Analysis Result:

| Collision | Content (relative value) of |
|---|---|
| ion | containing-fullerene |
| Used | 8 |

### Unused 1

From the content data of containing-fullerene, it has been shown that a production efficiency of containing-fullerene is improved by irradiating collision ions to material molecules simultaneously with containment target ions.

### INDUSTRIAL APPLICABILITY

As described above, the material film production method and production apparatus according to the present invention are excellent in controllability of implantation target ion density, and can be easily optimized in production condition of material films such as containing-fullerene, hetero-fullerene, and the like. Further, simultaneous implantation of containment target ions and collision ions is useful for improving a production efficiency of a material film for containing therein containment target atom(s), containment target molecule(s), or the like each having a larger diameter.

1. A material film production method, characterized in that the method comprises:
generating plasma including implantation target ions;
applying a control voltage to an electric potential body in contact with said plasma to thereby control a density of said implantation target ions;
irradiating said plasma toward a deposition-assistance substrate;
applying a bias voltage of a polarity opposite to that of said implantation target ions to said deposition-assistance substrate, to thereby provide said implantation target ions with acceleration energies, respectively; and
implanting said implantation target ions into a material film.

2. The material film production method of claim 1, characterized in that the method further comprises:
measuring an electric current flowing between said deposition-assistance substrate and a bias power supply for applying said bias voltage thereto, to thereby measure the density of said implantation target ions.

3. A material film production method, characterized in that the method comprises:
generating plasma including containment target ions and collision ions having the same polarity as said containment target ions;
irradiating said plasma toward a deposition-assistance substrate;
applying a bias voltage of a polarity opposite to that of said containment target ions to said deposition-assistance substrate, to thereby provide said containment target ions and said collision ions with acceleration energies, respectively; and
colliding said collision ions with material molecules constituting a material film, to thereby cause said material molecules to internally contain said containment target ions, respectively.

4. The material film production apparatus of claim 1, characterized in that the method further comprises:
depositing said material film on said deposition-assistance substrate, simultaneously with the irradiation of said plasma toward said deposition-assistance substrate.

5. The material film production method of claim 1, characterized in that the method further comprises:
irradiating said plasma onto said material film previously deposited on said deposition-assistance substrate.

6. A material film production method, characterized in that the method comprises:
generating plasma including collision ions;
irradiating said plasma toward a material film previously deposited on said deposition-assistance substrate;
simultaneously therewith, shooting vapor comprising containment target molecules toward said material film;
colliding said collision ions with material molecules constituting the material film; and
simultaneously therewith, causing said material molecules to internally contain said containment target molecules, respectively.

7. The material film production method of claim 1, characterized in that the method further comprises:
transporting said generated plasma by a magnetic field to thereby irradiate said plasma toward said deposition-assistance substrate.

8. The material film production method of claim 1, characterized in that said material film is a film comprising fullerene or nanotube.

9. The material film production method of claim 1, characterized in that said implantation target ions or said containment target ions are alkali metal ions, nitrogen ions, or halogen ions.

10. The material film production method of claim 6, characterized in that said containment target substance is TTF, TDAE, TMTSF, pentacene, tetracene, anthracene, TCNQ, Alq₃, or F₄TCNQ.

11. The material film production method of claim 3, characterized in that said collision ions each have a diameter of 3.0□ or larger.

12. The material film production method of claim 11, characterized in that said collision ions are fullerene positive ions or fullerene negative ions, respectively.

13. A material film production apparatus comprising:
a vacuum vessel;
magnetic field generation means;
plasma generation means for generating plasma including implantation target ions;
an electric potential body configured to control a density of said implantation target ions by applying a control voltage to said electric potential body;
a deposition-assistance substrate for depositing a material film thereon; and
a bias power supply configured to apply a bias voltage to said deposition-assistance substrate.

14. The material film production apparatus of claim 13, characterized in that said electric potential body comprises electroconductive wires in a lattice pattern.

15. A material film production apparatus comprising:
a vacuum vessel;
magnetic field generation means;
plasma generation means for generating plasma including containment target ions;
collision ion generation means for generating collision ions;
a deposition-assistance substrate for depositing a material film thereon; and
a bias power supply configured to apply a bias voltage to said deposition-assistance substrate.

16. A material film production apparatus comprising:
a vacuum vessel;
magnetic field generation means;
plasma generation means for generating plasma including collision ions;
a deposition-assistance substrate for depositing a material film thereon;
containment target molecule shooting means for shooting vapor including containment target molecules to said deposition-assistance substrate; and
a bias power supply configured to apply a bias voltage to said deposition-assistance substrate.
